(19) United States
(12) Patent Application Publication
(10) Pub. No.: US 2011/0009273 A1
(43) Pub. Date: Jan. 13, 2011

(54) RE123-BASED OXIDE SUPERCONDUCTOR AND METHOD OF PRODUCTION OF SAME

(76) Inventors: Sergey Lee, Tokyo (JP); Koichi Nakao, Tokyo (JP); Noriko Chikumoto, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 12/677,385

(22) PCT Filed: Sep. 12, 2008
(86) PCT No.: PCT/JP2008/066932

§ 371 Date: Mar. 10, 2010

(30) Foreign Application Priority Data
Sep. 14, 2007 (JP) 2007-239908

(51) Int. Cl. H01L 39/02; H01L 39/24

(52) U.S. Cl. 505/150; 505/470; 427/597; 428/702

(57) ABSTRACT

A method of production of a RE123-based oxide superconductor, said method of production of a RE123-based oxide superconductor characterized by comprising (i) firing a pulse laser at an oxide-based target including RE, Ba, and Cu satisfying the following formulas (1) and (2) to form a plume and (ii) holding a substrate in that plume to form an RE123-based oxide superconducting film:

0.8≦2RE/Ba<1.0 (1)

0.8≦3Ba/2Cu<1.0 (2)
where, RE is one or more of Y, La, Nd, Sm, Eu, Gd, Dy, Ho, and Er

### TECHNICAL FIELD

The present invention relates to a RE123-based oxide superconductor superior in critical current characteristic and a method of production of the same. Here, the RE123-based oxide means an RE-Ba—Cu-based oxide expressed by the chemical formula RE_{1±x}Ba_{2±y}Cu_{3±z}O_{7-δ} (RE: one or more of Y, La, Nd, Sm, Eu, Gd, Dy, Ho, and Er).

### BACKGROUND ART

In recent years, there has been active R&D going on, mainly in Japan and the U.S., in the technology of using oxide superconducting materials to produce superconducting wire. The pulse laser deposition method (PLD method) enables the formation of a superconducting film having a high critical current, so is one promising technology.

To commercialize a superconducting wire, it is essential to not only (i) form a superconducting film on a metal substrate, but also to (ii) increase the critical current (Ic) of the superconducting film. One measure for raising the critical current (Ic) is to increase the thickness of the superconducting film. Even if using the PLD method to increase the film thickness, the critical current (Ic) becomes saturated without increasing proportionally to the film thickness. This is becoming a major problem.

The saturation phenomenon of the critical current (Ic) is believed to be caused by the heat balance at the time of film formation changing along with an increase in the film thickness and, as a result, the temperature at the surface of the film formed fluctuating and the crystal structure responsible for the superconductivity characteristic not being homogenously formed in the film thickness direction.

Based on this, the method of adjusting the heating temperature of the substrate for each film formed so that the temperature of the film surface becomes constant has been proposed (see Journal of the Japan Institute of Metals, 68 (2004), page 718 to 722), but (x) controlling the temperature conditions for each film formed is complicated, further, (y) even if optimally controlling the temperature conditions, this is not efficient from the viewpoint of the film forming speed, and, furthermore, (z) even if a thick film can be formed, a 300 A/cm width critical current (Ic) sufficient for practical use cannot necessarily be obtained with good reproducibility.

Further, in practical application, it is necessary to also raise the critical current (Ic) characteristic in a magnetic field. For example, in a 3 T magnetic field, a 30 A/cm width or more critical current (Ic) characteristic is preferable in practice, but there are almost no examples of reports on this.

One of the reasons why a critical current (Ic) characteristic sufficient for practical use has not been obtained as a wire material is that when forming a RE123-based oxide superconducting film, a Ba-based compound is formed at the crystal grain boundaries of the RE123-based oxide.

A Ba-based compound weakens the bonds between the crystal grains, so becomes a cause remarkably degrading the critical current characteristic not only in its own magnetic field, but particularly in an external magnetic field. Furthermore, it becomes a barrier at the time of oxygen treatment after film formation and becomes a cause preventing the sufficient introduction of the oxygen required for making a RE123-based oxide superconducting.

Further, the Ba-based compound reacts with the moisture or carbon dioxide in the air along with time and forms different compounds causing degradation of the superconductivity characteristic.

For this reason, when using the PLD method to form a RE123-based oxide superconducting film, it is necessary to select film forming conditions where no Ba-based compound will be formed.

On the other hand, a Gd123-based oxide is an interesting material as a material for a superconducting wire such as (a) a critical temperature Tc of 94K, high even in RE123-based oxides, and, furthermore, (b) a narrow range of solid solution of Gd—Ba and easy avoidance of a drop in the critical temperature Tc.

The inventors, in consideration of the actual state of film-forming technology relating to RE123-based oxides, provide a method of using the PLD method to form a RE123-based oxide superconducting film on a long metal substrate (see Japanese Patent Publication (A) No. 2007-115592).

According to the above method, it is possible to produce a long RE123-based oxide superconducting material superior in critical current density characteristic, so the feasibility of the RE123-based superconducting wire becomes greater.

However, the above method suppresses the formation of a Ba-based compound by holding the metal substrate outside the plume a predetermined distance from the top (tip) of the plume, so requires a long time for film formation and is not necessarily good in film forming efficiency, that is, efficiency of utilization of raw materials (yield).

For efficient film formation by the PLD method, the method of placing the substrate near the plume or bringing it into contact with the plume has been proposed (see Japanese Patent Publication (A) No. 07-68161, Japanese Patent Publication (A) No. 07-88359, Japanese Patent Publication (A) No. 2005-42131, Japanese Patent Publication (A) No. 2005-89793, and U.S. Pat. No. 5,168,097). Further, the method of attaching the substrate to the plume for film formation has been proposed (see Japanese Patent Publication (A) No. 2003-306764).

According to the above methods, it is possible to form a Y123-based oxide superconducting film relatively efficiently, but if trying to obtain a 1 μm or more film thickness, the critical current characteristic will not be improved but will rather end up dropping in some cases.

Further, even if applying the above methods to formation of a RE123-based oxide superconducting film including RE with an ion radius larger than Y, the desired critical current characteristic cannot be obtained, so it is not possible to apply this to formation of a RE123-based oxide superconducting film.

In the final analysis, at the present, a practical PLD method able to efficiently form a RE123-based oxide superconducting film having the required composition and film thickness and superior in critical current (Ic) characteristic on a substrate at the required film forming speed has not been developed.

### DISCLOSURE OF INVENTION

In the past, in the PLD method, to raise the film forming speed, the number of pulses of the laser fired at the target has been increased or the laser power has been increased. However, whichever the technique, along with a rise in the film forming speed, a coarse impurity phase degrading the superconductivity characteristic is formed in the film structure and a drop in the critical current density (Jc) is invited.

This trend is particularly remarkable in the case of increasing the thickness of the film. In the final analysis, with the conventional techniques, there are limits to the improvement of the critical current.

The present invention, in consideration of the current state of film forming technology based on the PLD method, has as its object the formation of a RE123-based oxide superconducting film of a required thickness having a uniform and dense c-axis oriented crystal structure in the thickness direction on a metal substrate required for realization of superconducting wire by a faster film forming speed than in the past and production of a RE123-based oxide superconductor having a superior critical current characteristic sufficient for practical use in its own magnetic field and in an external magnetic field.

In the PLD method, to form a high quality superconducting film, in most cases, the substrate is held away from the tip of the plume (outside of the plume), but the film forming speed is slow, the film properties (film thickness, composition, structure, characteristics, etc.) are low in reproducibility, and only a crystal structure with a narrow homogeneous crystal area responsible for the superconductivity characteristic can be obtained. In the final analysis, the conventional PLD method is a film forming method hard to use for the process of production of a superconducting wire etc.

The inventors wondered if the cause for the narrow homogeneous crystal area in the film structure and, further, the cause of the low reproducibility in film properties in the formed film was the “flicker of the plume” due to the minute fluctuations in the laser power or atmospheric gas partial pressure, the minute changes in the surface conditions of the target, etc. (all unavoidable fluctuations and changes) and came up with the idea of eliminating the adverse effects caused by “flicker of the plume” by forming the film while holding the substrate in the plume.

That is, the inventors expected that if holding the substrate in the plume, the length between the target and substrate would become narrower and also the plume would be crushed in shape and spread over the substrate surface and as a result (i) the film forming speed would greatly rise, (ii) the homogeneous film forming area would increase at the substrate surface, and (iii) due to the synergistic action of these factors, the adverse effects caused by the “flicker of the plume” would be eliminated and a superconducting film with a uniform composition and a homogeneous crystal structure responsible for the superconductivity characteristic would be formed by a faster film forming speed than in the past and with a better reproducibility of the film properties.

Furthermore, based on the experimental fact that in a RE123-based oxide superconducting film, a Ba-based compound formed at the grain boundaries of the c-axis oriented crystals responsible for the superconductivity characteristic degrades the superconductivity characteristic, the inventors came up with the idea that Ba is preferably in excess compared with not only the RE, but also the Cu from the stoichiometric composition.

Further, with the above idea, the inventors changed the composition of the RE, Ba, and Cu contained in the oxide-based target to form RE123-based oxide superconducting films and studied the film properties (film thickness, composition, structure, characteristics, etc.)

As a result, the inventors discovered that “if forming the film while holding the substrate in the plume formed by firing a pulse laser at an oxide-based target containing RE, Ba, and Cu in a required composition ratio, it is possible to form a required thickness of RE-based 123-based oxide superconducting film having a uniform, dense c-axis oriented crystal structure on the substrate and superior in critical current characteristics by a faster film forming speed than the past”.

The present invention was made based on the above discovery and has as its gist the following:

(1) A method of production of a RE123-based oxide superconductor, said method of production of a RE123-based oxide superconductor characterized by comprising

(i) firing a pulse laser at an oxide-based target including RE, Ba, and Cu satisfying the following formulas (1) and (2) to form a plume and

(ii) holding a substrate in that plume to form an RE123-based oxide superconducting film:

0.8≦2RE/Ba<1.0 (1)

0.8≦3Ba/2Cu<1.0 (2)

where, RE is one or more of Y, La, Nd, Sm, Eu, Gd, Dy, Ho, and Er

(2) A method of production of a RE123-based oxide superconductor as set forth in (1) characterized by adding to said oxide-based target, as a material of a nonsuperconducting substance to be introduced dispersed into the RE123-based oxide superconducting film, one or more of ZrO₂, BaZrO₃, BaSnO₃, BaCeO₃, BaHfO₃, and BaRuO₃ in a total of 7 mol % or less.

(3) A method of production of a RE123-based oxide superconductor as set forth in (1) or (2) characterized by holding said substrate at a position satisfying the following formulas (3):

L=α·H (3)

where,

L: length between target and substrate (cm)

H: height of plume without substrate (cm)

α: substrate position coefficient, 0.6≦α≦0.9

(4) A method of production of a RE123-based oxide superconductor as set forth in (1) or (3) characterized in that said RE123-based oxide superconducting film has a composition satisfying the following formulas (4) and (5) :

1.0≦2RE/Ba≦1.2 (4)

0.8≦3Ba/2Cu<1.0 (5)

(5) A method of production of a RE123-based oxide superconductor as set forth in (2) or (3) characterized in that said RE123-based oxide superconducting film has a superconducting phase of a composition satisfying the following formulas (4) and (5):

1.0≦2RE/Ba≦1.2 (4)

0.8≦3Ba/2Cu<1.0 (5)

(6) A method of production of a RE123-based oxide superconductor as set forth in any one of (1) to (5) characterized by determining a composition of an oxide-based target satisfying said formulas (1) and (2) in accordance with the following procedures (i) to (vi):

(i) flexibly applying said formula (3) to select at least two substrate position coefficients α_{A} and α_{B} in a range of 1<α≦1.5;

(ii) holding the substrate vertical to a center axis of the plume at two positions A (L_{A}=α_{A}H) and B (L_{B}=α_{B}H) on the center axis of the plume and firing a pulse laser at an oxide-based target of composition ratios 2RE/Ba=a and 3Ba/2Cu=b to form a film, wherein

(ii-1) making the film composition ratios 2RE/Ba and 3Ba/2Cu at the position A respectively a_{A} and b_{A} and

(ii-2) making the film composition ratios 2RE/Ba and 3Ba/2Cu at the position B respectively a_{B} and b_{B},

(iii) setting a film composition ratio coefficient f(α), wherein

(iii-1) determining a film composition ratio coefficient fₐ(α) based on the two points of (α_{A}, a_{A}) and (α_{B}, a_{B}) and

(iii-2) determining a film composition ratio coefficient f_{b}(α) based on the two points of (α_{A}, b_{A}) and (α_{B}, b_{B}),

(iv) entering α=α_{c}(<1) into fₐ(α) to calculate an estimated film composition ratio fₐ(α_{c})=a_{c} when forming a film by holding the substrate vertical to the center axis at the position of the substrate position coefficient α_{c} and entering α=1 into f_{b}(α) to calculate an estimated film composition ratio f_{b}(1)=b₁ when forming a film by holding the substrate vertical to the center axis at the tip of the plume, wherein making this b₁ the estimated film composition ratio b_{c} at the position of the substrate position coefficient α_{c}.

(v) comparing the calculated value a_{c} and the following formula (4) and comparing the calculated value b_{c} (=b₁) and the following formula (5), wherein

(v-1) if 1.0≦a_{c}≦1.2 and 0.8≦b_{c}(=b₁)<1.0, determining the composition ratios a (=2RE/Ba) and b (=3Ba/2Cu) as the composition ratios of the oxide-based target and

(v-2) if a_{c}<1.0 or 1.2<a_{c} and/or b_{c} (=b₁)<0.8 or 1.0≦b_{c} (=b₁), using the following procedure (vi) to determine the composition ratios a (=2RE/Ba) and b (=3Ba/2Cu) of the oxide-based target, and

(vi) calculating a_{c}−(1.0+1.2)/2=Δa and/or b_{c} (=b₁)−(0.8+1.0)/2=Δb and determining the composition ratios a (=2RE/Ba) and b (=3Ba/2Cu) of the oxide-based target as (a−Δa) and (b−Δb):

1.0≦2RE/Ba≦1.2 (4)

0.8≦3Ba/2Cu<1.0 (5)

(7) A method of production of a RE123-based oxide superconductor as set forth in any one of (1) to (6) characterized in that the pulse laser fired at said oxide-based target has an energy density of 2 to 5 J/cm².

(8) A method of production of a RE123-based oxide superconductor as set forth in any one of (1) to (7) characterized by forming said RE123-based oxide superconducting film at a 0.8 A/pulse or more of film forming speed.

(9) A method of production of a RE123-based oxide superconductor as set forth in any one of (1) to (8) characterized in that in said RE123-based oxide superconducting film, (i) a film thickness is 1.0 μm or more and (ii) c-axis oriented crystals are present over the entire thickness direction in a volume rate of 80% or more.

(10) A method of production of a RE123-based oxide superconductor as set forth in any one of (1) to (9) characterized in that said RE is Gd.

(11) A method of production of a RE123-based oxide superconductor as set forth in any one of (1) to (10) characterized in that said substrate is a metal substrate.

(12) An RE123-based oxide superconductor characterized by being produced by a method of production of a RE123-based oxide superconductor as set forth in any one of (1) to (11).

(13) An RE123-based oxide superconductor produced by a method of production of a RE123-based oxide superconductor as set forth in any one of (1), (3), (4), and (6) to (11), said RE123-based oxide superconductor characterized in that the RE123-based oxide superconducting film has a 40 A/cm width or more critical current characteristic in a 3 T magnetic field.

(14) An RE123-based oxide superconductor as set forth in (13) characterized in that said RE123-based oxide superconducting film has a composition satisfying the following formulas (4) and (5):

1.0≦2RE/Ba≦1.2 (4)

0.8≦3Ba/2Cu<1.0 (5)

(15) An RE123-based oxide superconductor produced by a method of production of a RE123-based oxide superconductor as set forth in any one of (2), (3), and (5) to (11), said RE123-based oxide superconductor characterized in that the RE123-based oxide superconducting film has a 60 A/cm width or more critical current characteristic in a 3 T magnetic field.

(16) An RE123-based oxide superconductor as set forth in (15) characterized in that said RE123-based oxide superconducting film has a superconducting phase of a composition satisfying the following formulas (4) and (5):

1.0≦2RE/Ba≦1.2 (4)

0.8≦3Ba/2Cu<1.0 (5)

(17) An RE123-based oxide superconductor as set forth in any one of (12) to (16) characterized in that in said RE123-based oxide superconducting film, (i) a film thickness is 1.0 μm or more and (ii) c-axis oriented crystals are present over the entire thickness direction in a volume rate of 80% or more.

According to the present invention, it is possible to provide a RE123-based oxide superconductor which is comprised of a substrate on which a RE123-based oxide superconducting film with Ba less than RE from the stoichiometric composition and equal to or less than Cu from the stoichiometric composition is formed by a film forming speed faster than the past and with good reproducibility of film properties and which has superior critical current characteristic sufficient for practical use in its own magnetic field and an external magnetic field.

### BRIEF DESCRIPTION OF DRAWINGS

FIG. 1 is a view showing the relationship between the length between the target and substrate (T-S length) and the composition ratio of the Gd123-based oxide superconducting film.

FIG. 2 is a view showing an embodiment of a plume when holding a substrate in a plume.

FIG. 3 is a view showing the relationship between the length between the target and substrate (T-S length) and the film forming speed (nm/sec).

FIG. 4 is a view showing the X-ray diffraction intensity of a Gd123-based oxide superconducting film when forming a film while changing the length between the target and substrate (T-S length). (a) shows the X-ray diffraction intensity when forming a film using a Gd₁Ba₂Cu₃ oxide-based target, while (b) shows the X-ray diffraction intensity when forming a film using a Gd_{0.9}Ba₂Cu_{3.3} oxide-based target.

FIG. 5 is a view showing the relationship between length between the target and substrate (T-S length) and the critical current Ic (A/cm width).

FIG. 6 is a view showing the relationship between the length between the target and substrate (T-S length) and the composition ratio of the Gd123-based oxide superconducting film.

FIG. 7 is a view showing the crystal structure of a Gd123-based oxide superconducting film. (a) shows the crystal structure of a Gd123-based oxide superconducting film formed using a Gd₁Ba₂Cu₃ oxide-based target, while (b) shows the crystal structure of a Gd123-based oxide superconducting film formed using a Gd_{0.9}Ba₂Cu_{3.3} oxide-based target (2Gd/Ba=0.9, 3Ba/2Cu=0.91).

FIG. 8 is a view showing the relationship between the composition of a target and the film composition when forming a film with a length between the target and substrate (T-S length) of 5 cm.

FIG. 9 is a view showing the technique for determining the composition of the target. (a) shows the relationship between he plume height H and substrate position, while (b) shows the calculation technique.

FIG. 10 is a view showing the relationship between a magnetic field and a critical current Ic (A/cm width).

FIG. 11 is a view showing the relationship between a magnetic field and a critical current Ic (A/cm width).

FIG. 12 is a view showing the relationship between a film forming speed (Å/pulse) and a critical current Ic (A/cm width).

FIG. 13 is a view showing the relationship between a thickness of a Gd123-based oxide superconducting film and critical current Ic (A/cm width).

FIG. 14 is a view showing the relationship between a thickness and critical current Ic (A/cm width) of a Gd123-based oxide superconducting film containing a nonsuperconducting phase.

FIG. 15 is a view showing the relationship between a magnetic field and a critical current Ic (A/cm width).

FIG. 16 is a view showing the relationship between a direction of a magnetic field and a critical current Ic (A/cm width).

FIG. 17 is a view showing the relationship between a magnetic field and a critical current Ic (A/cm width) of a Gd123-based oxide superconducting film containing a nonsuperconducting phase.

FIG. 18 is a view showing the relationship between a direction of a magnetic field and a critical current Ic (A/cm width).

FIG. 19 is a view showing the relationship between a direction of a magnetic field and a critical current Ic (A/cm width).

### BEST MODE FOR CARRYING OUT THE INVENTION

The present invention, as explained above, was made based on the discovery that “if forming the film while holding the substrate in the plume formed by firing a pulse laser at an oxide-based target containing RE, Ba, and Cu in a required composition ratio, it is possible to form a required thickness of RE-based 123-based oxide superconducting film having a uniform, dense c-axis oriented crystal structure on the substrate and superior in critical current characteristics by a faster film forming speed than the past”.

Below, the present invention will be explained in detail.

### 1) Technical Significance of Growing Film in a Plume

First, the technical significance when forming a film while holding the substrate in the plume will be explained.

The inventors, taking as an example a Gd123-based oxide with a narrow RE-Ba solid solution region and a high critical temperature Tc (=94K), used an “oxide-based target including Gd, Ba, and Cu by composition ratios of 2Gd/Ba=1 and 3Ba/2Cu=1” (below, sometimes referred to as a “Gd₁Ba₂Cu₃ oxide-based target”) and changed the length between the target and substrate (below, sometimes referred to as “T-S length”) in the range of 5 to 9 cm so as to form Gd123-based oxide superconducting films on substrates (below, sometimes referred to as the “Gd123-based oxide film”) and investigated the compositions of the films (below, sometimes referred to as the “film composition”).

Each film was grown at a substrate temperature: 770° C., oxygen partial pressure: 350 mmTorr, and laser power: 100 mJ or 200 mJ.

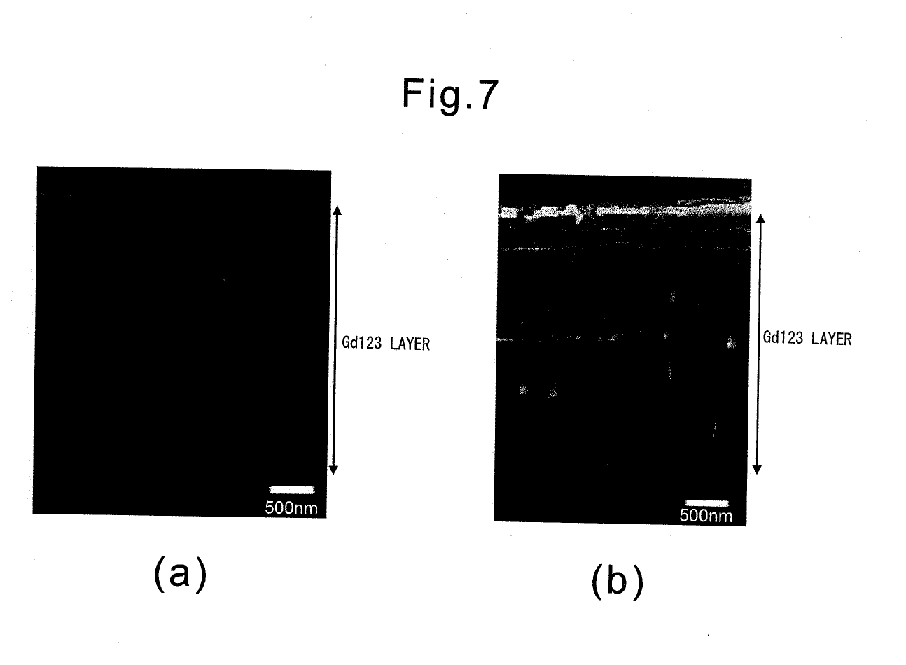

If defining the tip of the plume in accordance with the definition described in Japanese Patent Publication (A) No. 2007-115592 (see the same publication, FIG. 7), the distance from the target to the tip of the plume (height of plume without substrate) is 6 cm, so a T-S length of less than 6 cm means the substrate is held in the plume.

The results of the study are shown in FIG. 1. To statistically show the difference of the film composition from the stoichiometric composition, the ordinate shows the composition ratios “2Gd/Ba” and “3Ba/2Cu”. Note that the case of forming a film by a laser power of 100 mJ is shown by the black symbols, while the case of forming a film by 200 mJ is shown by white symbols.

In FIG. 1, if the composition ratios of the Gd123-based oxide film formed (below, sometimes referred to as the “film composition ratios”) are 2Gd/Ba=1.00 and 3Ba/2Cu=1.00, it means that a Gd123-based oxide film (Gd₁Ba₂Cu₃O_{7-δ} film) of a stoichiometric composition is formed.

When the T-S length is 9 cm (substrate is outside plume), even if the film forming conditions are constant (substrate temperature: 770° C., oxygen partial pressure: 350 mmTorr, and laser power: 100 mJ), “flicker of the plume” causes the film composition ratio 2Gd/Ba to change in the range of 0.90 to 1.10 and the film composition ratio 3Ba/2Cu to change in the range of 0.86 to 0.93.

The reason why the film composition ratio of the Gd123-based oxide film formed this way greatly changes is mainly that minute fluctuations in the laser power or atmospheric gas oxygen partial pressure and minute changes in the surface conditions of the target result in the direction of formation of the plume minutely inclining, the plume flickering, and fluctuations in the composition or form of the seed material in the film forming atmosphere near the surface of the substrate positioned outside of the plume.

However, when the T-S length is 5 cm (substrate is present in plume), the fluctuations in the film composition ratios “2Gd/Ba” and “3Ba/2Cu” are extremely small.

The reason is believed to be as follows:

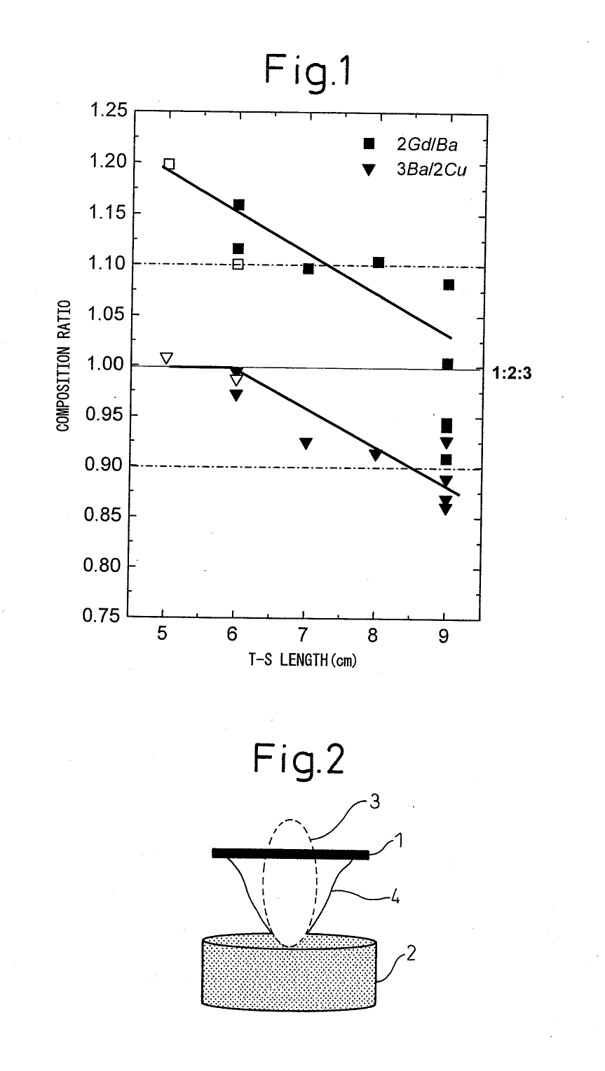

As shown schematically in FIG. 2, usually, a plume 3 is formed at the surface of the target 2. If holding the substrate 1 inside the plume 3, the plume 3 becomes a plume 4 of a shape with the tip of the plume crushed by the substrate. The film is formed in this state.

That is, a film is formed with the flat plume in contact with the substrate surface. Since the plume is a flat plume close to the target, the film-forming area with the uniform composition and form of the seed material extends over the substrate surface. Not only this, but even if the plume flickers, there is no effect and the film continues to be formed with the composition and form of the seed material in the film-forming atmosphere near the substrate surface maintained uniform.

This point is the technical significance of forming a film while holding the substrate in the plume.

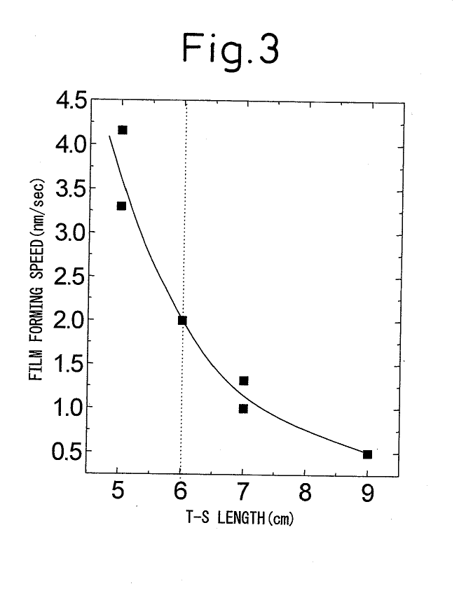

Further, the inventors also confirmed the technical significance of forming a film while holding the substrate in the plume as shown in FIG. 3 from the point of the film forming speed (nm/sec).

Note that, the film was grown at a substrate temperature: 770° C., oxygen partial pressure: 350 mmTorr, laser power: 100 mJ or 200 mJ, and laser frequency f: 40 Hz.

As shown in FIG. 3, when narrowing the T-S length, if the substrate is positioned in the plume (6 cm or less), the film forming speed rapidly rises to 2.0 nm/sec or more.

The reason why the film forming speed rapidly rises is believed to be that the concentration of the see material metal plasma in the plume is higher than the concentration outside the plume and the supersaturation degree becomes higher, so an atmosphere is formed facilitating nucleation for crystal growth at the surface of the substrate held in the plume and the film forms in that atmosphere.

Furthermore, the inventors confirmed the technical significance when forming a film while holding the substrate in the plume from the viewpoint of the crystal structure.

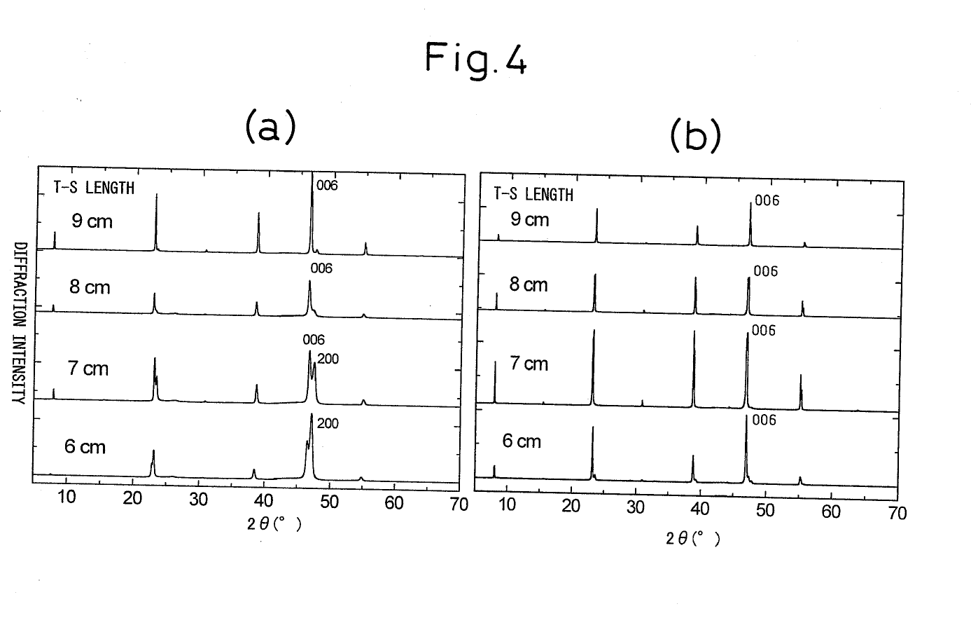

FIG. 4 shows the X-ray diffraction intensity of a Gd123-based oxide superconducting film formed by changing the T-S length in the range of 6 to 9 cm (plume height: 6 cm). FIG. 4(a) shows the X-ray diffraction intensity when forming a film using a Gd₁Ba₂Cu₃ oxide-based target, while FIG. 4(b) shows the X-ray diffraction intensity when forming a film using “an oxide-based target including Gd, Ba, and Cu by composition ratios of 2Gd/Ba=0.90 and 3Ba/2Cu=0.91” (below, sometimes referred to as “Gd_{0.9}Ba₂Cu_{3.3} oxide-based target”).

According to FIG. 4(a), when forming a film using a Gd₁Ba₂Cu₃ oxide-based target, the narrower the T-S length, the greater the amount of a-axis oriented crystal grains in the film structure (in the figure, see the X-ray diffraction intensity of the (200) plane of the crystal plane shown by (hkl)).

On the other hand, according to FIG. 4(b), when forming a film using a Gd_{0.9}Ba₂Cu_{3.3} oxide-based target, even if narrowing the T-S length, the X-ray diffraction intensity of the (200) plane showing the presence of the a-axis oriented crystal grains remains small.

Here, the X-ray diffraction intensity of the (hkl) plane of the crystal is defined as I(hkl) and the X-ray diffraction intensity ratio serving as an indicator of the amount of a-axis oriented crystal grains present in the crystal structure (below, sometimes referred to as “a-axis crystal grains” or “a-axis grains”) is defined by the formula I(200)/{I(006)+I(200)}×100. Table 1 shows the X-ray diffraction intensity ratio in the case when forming a film while holding the substrate in the plume (T-S length: 5 cm) and using a Gd₁Ba₂Cu₃ oxide-based target (in the table, Gd123) and Gd_{0.9}Ba₂Cu_{3.3} oxide-based target (in the table, Gd-poor.Cu-rich).

TABLE 1

| | X-ray diffraction intensity ratio of a- |
|---|---|
| | axis crystal grains |
| Target material | [I (200)/{I (006) + I (200)}] × 100 |
| GdBa₂Cu₃Oy | 3% |
| Gd-123 | |
| Gd_{0.9}Ba₂Cu_{3.3}Oy | 2% |
| Gd-poor · Cu-rich | |

In the case of the Gd_{0.9}Ba₂Cu_{3.3} oxide-based target, based on the trend appearing in FIG. 4(b), the X-ray diffraction intensity ratio of the a-axis crystal grains is small. In the case of a Gd₁Ba₂Cu₃ oxide-based target, reflecting the trend appearing in FIG. 4(a), the X-ray diffraction intensity ratio of the a-axis crystal grains becomes smaller.

In the past, the formation and growth of a-axis crystal grains reportedly depend on the concentration and oxidation state of the seed material (supersaturation degree) and the magnitude of the kinetic energy. However, this is said to be predicated on the formation of the film while holding the substrate outside the plume.

As shown in Table 1, if holding the substrate in the plume, the X-ray diffraction intensity ratio of a-axis crystal grains is small no matter which target is used. The reason is believed to be as follows:

In the material atmosphere formed in laser deposition, there are ionized metal (metal plasma), oxygen plasma, and neutral molecules of metal and oxygen bonded together. When these reach the substrate, however, the metal plasma is greater in mobility compared with neutral molecules. Further, the greater the mobility of the seed material, the easier the growth of c-axis oriented crystals.

In the plume, the degree of oxidation of the seed metal material is smaller than outside the plume, so the ratio of the metal ions in the seed material reaching the substrate is high. On the other hand, outside the plume, the ratio of the neutralized molecules (neutral molecules of metal and oxygen bonded together) increases, so the harder the growth of c-axis oriented crystals.

In the conventional PLD method holding the substrate outside the plume, to raise the mobility of the metal plasma reaching the substrate, it is necessary to raise the substrate temperature, but there is a limit to the rise in the substrate temperature.

That is, if holding the substrate in the plume, the plume is crushed by the substrate in shape and spreads out to the substrate surface (see FIG. 2). Near the substrate surface, the film is formed in a state with the concentration and composition ratio of the seed material in the film forming atmosphere including the metal plasma in a high concentration maintained substantially constant. Therefore, the film is formed at a faster film forming speed than the past. As a result, this means the film structure is not formed with a-axis oriented crystals or formation of a-axis oriented crystals is difficult and a film structure comprised almost entirely of c-axis oriented crystals is formed.

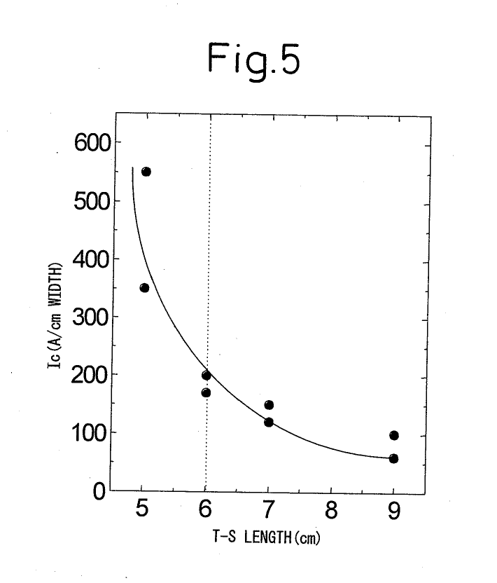

The critical current characteristic is a characteristic directly reflecting the quality of the uniformity and denseness of the c-axis oriented crystal structure, so the inventors measured the critical current characteristic of Gd123-based oxide superconducting films grown changing the T-S length. The results are shown in FIG. 5.

Note that the film was grown at a substrate temperature: 770° C., oxygen partial pressure: 350 mmTorr, laser power: 100 mJ or 200 mJ, and laser frequency: 40 Hz for 20 minutes.

As shown in FIG. 5, if growing the substrate held in the plume (T-S length: 5 cm), the critical current characteristic of the Gd123-based oxide superconducting film exceeds 200 A/cm width and is remarkably improved.

From this as well, the technical significance of growing a film while holding the substrate in the plume can be confirmed.

That is, if forming a film while holding a substrate in the plume, the adverse effects of “flicker of the plume” can be eliminated and a Gd123-based oxide film having the required thickness and composition, comprised of a high ratio of a c-axis oriented crystal structure, and extremely superior in critical current characteristic can be formed at a faster film forming speed than the past with a good reproducibility of the film properties.

This point is the technical significance of forming a film while holding the substrate in the plume and is a discovery forming the basis of the present invention.

### 2) Relationship Between Target Composition and Film Composition and Superconductivity Characteristic

Next, the inventors used several compositions of Gd—Ba—Cu oxide-based targets and formed Gd123-based oxide films while holding the substrates in the plume. They investigated the relationship between the film composition and superconductivity characteristic in those cases.

As shown in FIG. 1, when using a Gd₁Ba₂Cu₃ oxide-based target and the T-S length is 5 cm (substrate is present in plume), the film composition ratios 2Gd/Ba and 3Ba/2Cu are not adversely affected by “flicker of the plume” and fluctuations are small.

The inventors, further, confirmed that when using a Gd_{0.9}Ba₂Cu_{3.3} oxide-based target and forming a film while holding the substrate in the plume, the extent of the fluctuation in the film composition ratio is small.

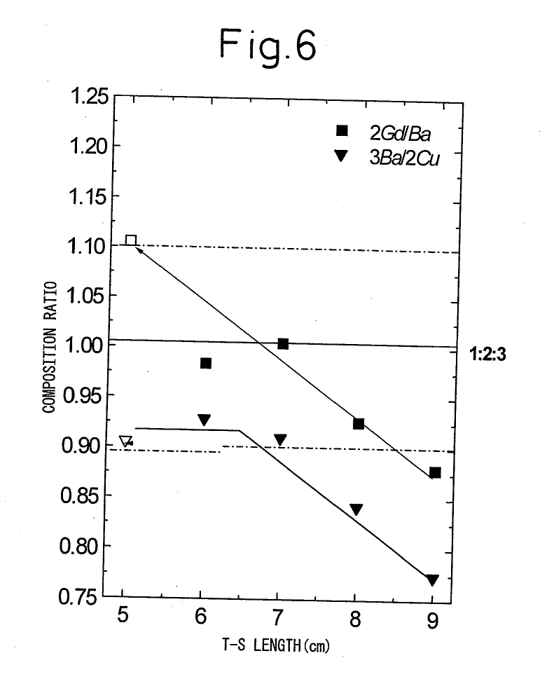

The results are shown in FIG. 6. Note that the film was grown by a substrate temperature: 770° C., oxygen partial pressure: 350 mmTorr, and laser power: 100 mJ or 200 mJ. In the figure, the white notations show the film grown by a laser power: 200 mJ.

As shown in FIG. 6, when the T-S length becomes narrow, the composition ratio 3Ba/2Cu of the Gd123-based oxide film increases, but when the T-S length is 6 cm or less, that is, the substrate is held in the plume, the composition ratio 3Ba/2Cu of the Gd123-based oxide film becomes saturated “near 0.90” and becomes a constant value.

This constant value is believed to reflect the composition ratio 3Ba/2Cu(=0.91) of the Gd_{0.9}Ba₂Cu_{3.3} oxide-based target used. The same is true even in the case of the Gd₁Ba₂Cu₃ oxide-based target shown in FIG. 1.

Further, as shown in FIG. 6, when the T-S length is 5 cm, the composition ratio 2Gd/Ba of the Gd123-based oxide film is about “1.1”, but this value is a value which can be approximated by the extension of the “linear relationship of the film composition ratio and T-S length” in the case of forming a film while holding the substrate outside the plume. The same is true for the case of the Gd₁Ba₂Cu₃ oxide-based target shown in FIG. 1.

The inventors discovered from the results of investigation shown in FIG. 1 and FIG. 6 that when forming a film while holding the substrate in the plume, the composition ratios “3Ba/2Cu” and “2Gd/Ba” of the Gd123-based oxide film can be guessed from the composition ratios “3Ba/2Cu” and “2Gd/Ba” of the Gd123-based oxide film formed while holding the substrate outside the plume.

That is, the inventors discovered that (x) the composition ratio 3Ba/2Cu of the Gd123-based oxide film formed while holding the substrate outside the plume can be approximated by the composition ratio of the Gd123-based oxide film formed while holding the substrate at the tip of the plume and (y) the composition ratio 2Gd/Ba of the similarly formed Gd123-based oxide film can be guessed based on the “linear relationship between the film composition ratio and the T-S length” when forming a film while holding the substrate outside the plume.

Here, Table 2 shows the film composition ratios and characteristics when forming films using a Gd₁Ba₂Cu₃ oxide-based target (in the table, Gd-123) and Gd_{0.9}Ba₂Cu_{3.3} oxide-based target (in the table, Gd-poor.Cu-rich) and the film composition ratios and characteristics when forming a film using an “oxide-based target including Gd, Ba, and Cu in composition ratios of 2Gd/Ba=1.05 and 3Ba/2Cu=0.95” (below, sometimes referred to as “Gd₁Ba_{1.9}Cu₃ oxide-based target” (in the table, sometimes referred to as “Ba-poor”).

TABLE 2

| | | | | | | I_{c}(3T) |
|---|---|---|---|---|---|---|
| | 2Gd/Ba | | 3Ba/2Cu | | | (45° from |
| Target | Target | | Target | | I_{c}(3T) | c-axis |
| material | material | Film | material | Film | (B//c) | direction) |
| GdBa₂Cu₃O_{y} | 1.00 | 1.20 | 1.00 | 1.01 | 28A | 15A |
| Gd-123 | | | | | | |
| GdBa_{1.9}Cu₃O_{y} | 1.05 | 1.25 | 0.95 | 0.95 | 40A | 25A |
| Ba-poor | | | | | | |
| Gd_{o.9}Ba₂Cu_{3.3}O_{y} | 0.9 | 1.1 | 0.91 | 0.91 | 50A | 38A |
| Gd-poor•Cu-rich | | | | | | |

In Table 2, the critical current (Ic) was measured for the case of applying a magnetic field 3 T parallel to the c-axis of the c-axis oriented crystals (vertical to the film surface) (in the table, B//c) and for the case of applying a magnetic field from a direction of 45° with respect to the c-axis (in the table, 45° from the c-axis).

The critical current (Ic) of the Gd123-based oxide film formed using a Gd₁Ba₂Cu₃ oxide-based target (Gd-123) is the highest value of the Ic reported in the past. The critical currents (Ic) of the Gd123-based oxide films formed using the Gd_{0.9}Ba₂Cu_{3.3} oxide-based target (Gd-poor.Cu-poor) and Gd₁Ba_{1.9}Cu₃ oxide-based target (Ba-poor) are unprecedentedly superior.

In this way, it is learned that an unprecedentedly superior critical current (Ic) is realized not only when the film composition ratio 2Gd/Ba is “1” or more, that is, Ba is excessively smaller compared with Gd from the stoichiometric composition, but also when the film composition ratio 3Ba/2Cu is “1” or less, that is, Ba is equal to or excessively smaller than Cu from the stoichiometric composition.

Above, the discoveries explained in the above “1) and 2)” are extremely important discoveries in realizing a thicker Gd123-based oxide film in the PLD method with good reproducibility of film properties while securing stability of the composition and uniformity and denseness of the structure.

The inventors obtained similar results when applying this discovery to formation of a RE123-based oxide superconducting film replacing this RE with another element other than Gd.

Here, FIG. 7 shows the cross-sectional TEM image of a Gd123-based oxide film. FIG. 7(a) shows the cross-sectional TEM image of a Gd123-based oxide film grown using a Gd_{0.9}Ba₂Cu_{3.3} oxide-based target with a T-S length of 5 cm, while FIG. 7(b) shows the cross-sectional TEM image of a Gd123-based oxide film grown using a Gd₁Ba₂Cu₃ oxide-based target with the same T-S length of 5 cm.

When growing a film using a Gd_{0.9}Ba₂Cu_{3.3} oxide-based target and when growing a film using a Gd₁Ba₂Cu₃ oxide-based target, the X-ray diffraction intensity ratios [I(200)/{I(006)+I(200)}]×100 of a-axis crystal grains become about the same (see Table 1), but, as shown in FIG. 7(a) and (b), the structure of a Gd123-based oxide film formed using a Gd_{0.9}Ba₂Cu_{3.3} oxide-based target (in the drawing, see Gd123 layer shown by the arrow range) is extremely uniform and dense (see FIG. 7(a)), while the structure of a Gd123-based oxide film formed using a Gd₁Ba₂Cu₃ oxide-based target has voids (see white spots in FIG. 7(b)) scattered in it.

The inventors analyzed this in detail and as a result learned that the voids form along with the rough precipitation of the nonsuperconducting phase Gd₂BaCuO₅ (RE211 phase).

The formation of such voids is a phenomenon which arises in a Gd123-based oxide film formed using a Gd₁Ba₂Cu₃ oxide-based target with a film composition ratio 2Gd/Ba=1.20 where Gd is present in excess compared with Ba from the stoichiometric composition.

Further, in a Gd123-based oxide film formed using a Gd₁Ba₂Cu₃ oxide-based target, not only are there voids and “a coarse RE211 phase (nonsuperconducting phase) of a particle size of tens to 100 s of μm” present, but a fine amount of Ba-based compound formed with a film composition ratio 3Ba/2Cu=1.01 (see Table 2) where Ba is present in excess compared with Cu from the stoichiometric composition partially obstructs the grain boundary bonds of the c-axis oriented crystal structure and prevents a high critical current (Ic) from being obtained.

Here, according to FIG. 1 and FIG. 6, the narrower the T-S length, the greater the amount of Gd, amount of Ba, and amount of Cu in the film of the Gd123-based oxide film. The increase in amount of Gd is faster than the increase in amount of Ba (see gradient of 2Gd/Ba), and the increase in the amount of Ba is faster than the increase in amount of Cu (see gradient of 3Ba/2Cu). In the final analysis, it is learned that the narrower the T-S length, the more the amount of Gd, amount of Ba, and amount of Cu in the film increase in the order of Gd>Ba>Cu, but the increase in elements in this order, according to the above-mentioned discovery relating to the film structure (formation of voids, formation of nonsuperconducting phase, formation of Ba compounds), induces formation of a coarse nonsuperconducting phase and can become a cause degrading the uniformity and denseness of the c-axis oriented crystal structure responsible for the critical current characteristic.

On the other hand, in a Gd123-based oxide film grown using a Gd_{0.9}Ba₂Cu_{3.3} oxide-based target, there are very few a-axis oriented crystal grains and a uniform dense c-axis oriented crystal structure is formed (see FIG. 7(a)). This c-axis oriented crystal structure is believed to be responsible for the superior critical current characteristic.

Here, from the critical current (Ic) shown in Table 2, it is learned that even when forming a film using a Gd₁Ba_{1.9}Cu₃ oxide-based target (2Gd/Ba=1.05, 3Ba/2Cu=0.95), at 2Gd/Ba=1.25, Gd becomes greatly excessive compared with Ba and a coarse nonsuperconducting phase is formed, so the critical current (Ic) is degraded from the case of forming a film using a Gd_{0.9}Ba₂Cu_{3.3} oxide-based target, but compared with the case of forming a film using a Gd₁Ba₂Cu₃ oxide-based target, the drop in the critical current (Ic) is smaller.

In this way, when growing a film using a Gd₁Ba_{1.9}Cu₃ oxide-based target, the reason why the drop in the critical current (Ic) is small is believed to be that the Gd₁Ba_{1.9}Cu₃ oxide-based target is 3Ba/2Cu=0.95 where the Ba is excessively small compared with the Cu from the stoichiometric composition, so in the film structure, no drop occurs in grain boundary bonds due to the formation of the Ba-based compound.

Therefore, when growing a film while holding the substrate in a plume, to obtain a film structure having superior critical current characteristics, it is necessary to select the composition of the Gd—Ba—Cu oxide-based target considering not only the film composition, but also the order of increase (Gd>Ba>Cu) of the Gd, Ba, and Cu having a great effect on the film structure.

That is, the composition of the Gd—Ba—Cu oxide-based target is an important film forming condition closely related to progress of film formation at a faster film forming speed than the past in the state where when holding the substrate in the plume, the plume is crushed by the substrate in shape and spreads to the substrate surface (see FIG. 2) and where a composition and form of the seed material in the film forming atmosphere near the substrate surface are maintained substantially uniformly. This is one of the discoveries found by the inventors and forming the basis of the present invention.

### 3) Composition of Gd—Ba—Cu Oxide-Based Target

Next, the inventors investigated the composition of a Gd—Ba—Cu oxide-based target with extremely few a-axis crystal grains and enabling the formation of a uniform, dense c-axis oriented crystal structure in the case of forming a Gd123-based oxide film while holding the substrate in the plume based on the above discovery.

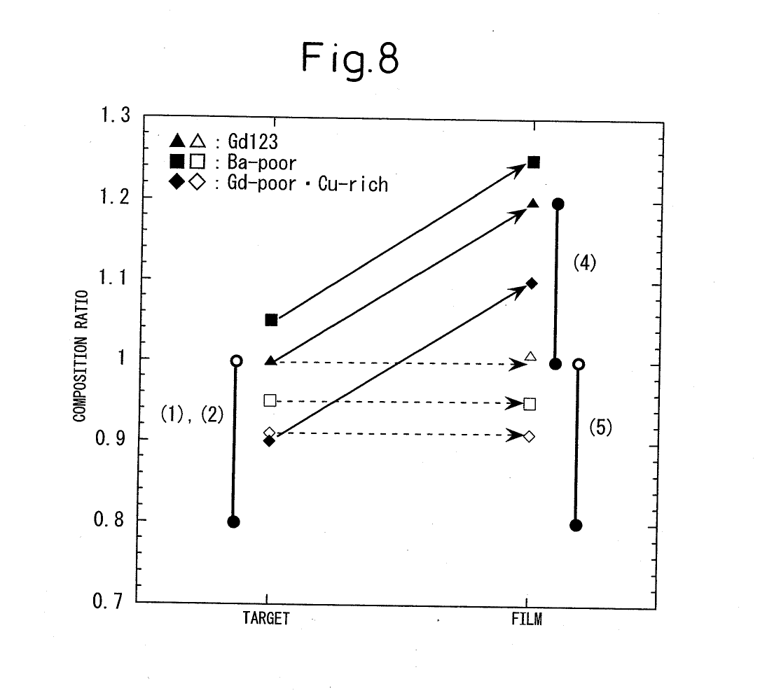

FIG. 8 shows the relationship between the composition ratios 2Gd/Ba and 3Ba/2Cu of the Gd—Ba—Cu oxide-based target shown in Table 2 and the composition ratios 2Gd/Ba and 3Ba/2Cu of the Gd123-based oxide superconducting film grown using the target.

That is, FIG. 8 shows the relationship of the composition ratios of the Gd₁Ba₂Cu₃ oxide-based target when forming a film by a T-S length of 5 cm (in the drawing, black triangles and white triangles: Gd-123), the composition ratios of the Gd₁Ba_{1.9}Cu₃ oxide-based target (in the drawing, the black squares and white squares: Ba-poor), and the composition ratios of the Gd_{0.9}Ba₂Cu_{3.3} oxide-based target (in the drawing, black diamonds and white diamonds: Gd-poor.Cu-rich) (2Gd/Ba and 3Ba/2Cu) and the composition ratios of the Gd123-based oxide film formed using these oxide-based target (2Gd/Ba and 3Ba/2Cu).

Here, the black triangles, black squares, and black diamonds show the composition ratio 2Gd/Ba, while the white triangles, white squares, and white diamonds show the composition ratio 3Ba/2Cu.

As shown in FIG. 8, the composition ratio 3Ba/2Cu of the Gd—Ba—Cu oxide-based target is reflected as is in the composition ratio 3Ba/2Cu of the Gd123-based oxide film (in the drawing, see white triangles, white squares, and white diamonds).

On the other hand, the composition ratio 2Gd/Ba of the Gd—Ba—Cu oxide-based target is reflected in the composition ratio 2Gd/Ba of the Gd123-based oxide film in accordance with the trend in increase of the film composition ratio 2Gd/Ba (see FIG. 1) (in the drawing, see black triangles, black squares, and black diamonds).

In the drawing, the ranges of the composition ratios 2Gd/Ba and 3Ba/2Cu of the oxide-based target defined by said formulas (1) and (2) (in each case, 0.8 to less than 1.0) are shown by black circle-white circle (in the drawing, see (1) and (2)), while the range of the composition ratio 2Gd/Ba (1.0 to 1.2) and range of 3Ba/2Cu (0.8 to less than 1.0) of the Gd123-based oxide film defined by said formulas (4) and (5) are shown by black circle-black circle (in the drawing, see (4)), and black circle-white circle (in the drawing, see (5)).

Below, the composition ratios 2Gd/Ba and 3Ba/2Cu will be explained.

### (1) Composition Ratio 2Gd/Ba

If the T-S length becomes narrower, the increase in the amount of Gd becomes faster than the increase in the amount of Ba (see FIG. 1). If the composition ratio 2Gd/Ba of the Gd—Ba—Cu oxide-based target is 1.0 or more, the Gd123-based oxide film will have a large amount of Gd present, a nonsuperconducting substance will be formed, and the c-axis oriented crystal structure responsible for the superconductivity characteristic will be degraded in uniformity and denseness.

Therefore, the composition ratio 2Gd/Ba of the Gd—Ba—Cu oxide-based target used in the present invention is made less than 1.0. Note that 2Gd/Ba is preferably 0.95 or less.

The 2Gd/Ba of the Gd123-based oxide film formed using a Gd—Ba—Cu oxide-based target where 2Gd/Ba is 1.0 is about 1.2 (see Table 2), but if the 2Gd/Ba of the Gd123-based oxide film becomes less than 1.0, the amount of Ba becomes excessive with respect to the amount of Gd. This becomes a cause of formation of Ba compounds obstructing the superconductivity characteristic.

Therefore, the composition ratio 2Gd/Ba of the Gd—Ba—Cu oxide-based target used in the present invention is made 0.8 or more. Note that 2Gd/Ba is preferably 0.85 or more.

If the composition ratio 2Gd/Ba of the Gd—Ba—Cu oxide-based target is 0.8 or more, the composition ratio 2Gd/Ba of the Gd123-based oxide film can be maintained at 1 or more (see Table 2).

### (2) Composition Ratio 3Ba/2Cu

As explained above, from FIG. 8, it will be understood that the composition ratio 3Ba/2Cu of the Gd—Ba—Cu oxide-based target is reflected as is in the composition ratio of the Gd123-based oxide superconducting film formed.

If using a Gd_{0.9}Ba₂Cu_{3.3} oxide-based target (Gd-poor.Cu-rich, 2Gd/Ba=0.90, 3Ba/2Cu=0.91), a Gd123-based oxide film having a superior critical current characteristic can be formed, but when using a Gd₁Ba₂Cu₃ oxide-based target (Gd-123, 2Gd/Ba=1, 3Ba/2Cu=1), the improvement in the critical current characteristic is not remarkable (see Table 2).

The reason is that when using a Gd₁Ba₂Cu₃ oxide-based target, as explained above, the value of 3Ba/2Cu of the Gd123-based oxide superconducting film becomes larger than “1” and Ba is excessively present in the film, so Ba compounds detrimental to the superconductivity characteristic are formed between crystal grains of the c-axis oriented crystals.

For this reason, the composition ratio 3Ba/2Cu of the Gd—Ba—Cu oxide-based target used in the present invention is made “less than 1.0” avoiding the stoichiometric composition ratio. Note that, 3Ba/2Cu is preferably 0.95 or less.

The Gd123-based oxide film exhibits a superior critical current characteristic based on the uniform and dense c-axis oriented crystal structure with 3Ba/2Cu: less than 1.0, but if 3Ba/2Cu is less than 0.8, Ba will become larger in degree of discrepancy from the stoichiometric composition, Cu will become excessive, CuO etc. will precipitate, and the crystal structure will fall in uniformity and denseness.

The composition ratio 3Ba/2Cu of the Gd123-based oxide film is based on the composition ratio 3Ba/2Cu of the Gd—Ba—Cu oxide-based target, so the composition ratio 3Ba/2Cu of the Gd—Ba—Cu oxide-based target used in the present invention is made “0.8 or more”. Note that 3Ba/2Cu is preferably 0.85 or more.

### 4) Features of Present Invention

### (1) Composition of RE-Ba—Cu Oxide-Based Target

The present invention, as explained above, was made based on the discovery that “if forming the film while holding the substrate in the plume formed by firing a pulse laser at an oxide-based target containing RE, Ba, and Cu in a required composition ratio, it is possible to form a required thickness of RE-based 123-based oxide superconducting film having a uniform, dense c-axis oriented crystal structure on the substrate and superior in critical current characteristics by a faster film forming speed than the past”.

Further, the basic concept of the present invention has as its first characteristic the use of an oxide-based target containing RE, Ba, and Cu satisfying the following formulas (1)and (2) (below, sometimes referred to as “the present invention target”) based on the results of experiments conducted using a Gd—Ba—Cu oxide-based target predicated on the above discovery:

0.82RE/Ba<1.0 (1)

0.83Ba/2Cu<1.0 (2)

Note that, 2RE/Ba, in the same way as when the RE is Gd, is preferably 0.85 to 0.95, while 3Ba/2Cu is preferably 0.85 to 0.95.

Here, RE is one or more of Y, La, Nd, Sm, Eu, Gd, Dy, Ho, and Er. These elements can be used as elements forming the RE123-based oxide in a range of composition not detracting from the superconductivity characteristic of critical current characteristic.

In particular, Gd is an element with a narrow Gd—Ba solid solution region and acting to raise the critical temperature (Tc), so is an element preferred as an element forming the present invention target. In addition, Nd, Sm, and Eu giving a critical temperature (Tc) of 94K or more are also elements preferred as elements forming the present invention target.

By using the present invention target where 0.8≦2RE/Ba<1.0 and 0.8≦3Ba/2Cu<1.0, it is possible to form a RE123-based oxide superconducting film superior in critical current characteristic on a substrate held in the plume with good reproducibility of film properties. The composition and characteristics of the RE123-based oxide superconducting film will be explained later.

If the nonsuperconducting substance is uniformly dispersed in the crystal structure of the RE123-based oxide superconducting film, the critical current characteristic is improved, so the present invention target may include, in addition to the RE, Ba, and Cu defined by the above formulas (1) and (2), a material supplying a nonsuperconducting substance comprised of one or more of ZrO₂, BaZrO₃, BaSnO₃, BaCeO₃, BaHfO₃, and BaRuO₃ in a total of 7 mol % or less.

If the target contains a material supplying a nonsuperconducting substance in over 7 mol %, the amount of nonsuperconducting substance introduced into the crystal structure of the RE123-based oxide superconducting film will become excessive and conversely the superconductivity characteristic will be impaired. Note that, the amount of addition of the material supplying the nonsuperconducting substance is preferably 5 mol % or less.

### (2) Base Material Position

The method of production of the present invention has as its second characteristic the formation of a film while holding the substrate at a position satisfying the following formula (3) predicated on said basic idea:

L=α·H (3)

L: length between target and substrate (cm)

H: height of plume without substrate (cm)

α: substrate position coefficient, 0.6≦α≦0.9

The method of production of the present invention defines the distance from the target to the tip of the plume (definition in accordance with definition described in Japanese Patent Publication (A) No. 2007-115592 (see FIG. 7) as the height of plume and defines the substrate position L in the plume (length between target and substrate [cm]=α·H [where a is a constant and 0.6≦α≦0.9]) based on the plume height H without the substrate.

The composition ratios (2Gd/Ba and 3Ba/2Cu) of the seed material sprayed to the substrate position L and forming the film forming atmosphere near the substrate surface directly govern the film composition ratio, so are important conditions in forming a RE123-based superconducting film having a superior critical current characteristic.

The inventors experimentally confirmed that in the above formula (3), when α>1, that is, when holding the substrate outside the plume, the plume height H changes due to the film forming conditions, in particular the ambient pressure, but the position dependency of the composition ratio of the seed material sprayed to the substrate position L and forming the film forming atmosphere near the substrate surface can be defined by the plume height H.

Therefore, the inventors employed L (=α·H[α: definition]) as an indicator defining the formation of the RE123-based oxide superconducting film.

Further, the inventors confirmed that when holding a substrate in the plume, that is, when α<1, the plume will be crushed to the substrate surface in shape and spread, so the composition ratio 3Ba/2Cu of the seed material sprayed to the substrate surface and forming the film forming atmosphere can be estimated by the composition ratio when α=1.

If α is less than 0.6, if the length between the target and substrate becomes too close, the directly sprayed particles (droplets) will adhere to the substrate surface or the effects of heat will easily be felt and it will become difficult to form a uniform and dense RE123-based oxide film over the entire substrate surface. For this reason, α is preferably 0.6 or more.

On the other hand, if a exceeds 0.9, the film will be formed at the tip of the plume and the film forming speed will not be able to be increased, so α is preferably 0.9 or less.

From the viewpoint of preventing the formation of almost all a-axis oriented crystal grains and obtaining a more uniform and dense c-axis oriented crystal structure, α is more preferably 0.75 to 0.85.

Note that, the inventors engaged in the above-mentioned film forming experiments with H=6 cm and L=5 cm, but 5 cm is the distance in the range of 6×0.75 to 6×0.85 (cm).

### (3) Film Composition

The RE123-based oxide superconducting film formed by the method of production of the present invention preferably has a composition satisfying the following formulas (4) and (5) even when containing a nonsuperconducting substance increasing the critical current (Ic) characteristic:

1.0≦2RE/Ba1.2 (4)

0.8≦3Ba/2Cu<1.0 (5)

Here, the above formula (4) shows that Ba is excessively smaller than RE from the stoichiometric composition, while the above formula (5) shows that Ba is excessively smaller than Cu from the stoichiometric composition.

The inventors disclosed a “RE123-based oxide superconducting film superior in critical current characteristic” where Ba satisfies the above formula (4)” in Japanese Patent Publication (A) No. 2007-115592, but furthermore obtained the discovery that to obtain a RE123-based oxide superconducting film superior in critical current characteristic, Ba also has to satisfy the above formula (5).

### (4) Determination of Suitable Target Composition

The composition of the RE, Ba, and Cu forming the RE-Ba—Cu oxide-based target used in the present invention is basically defined by said formulas (1) and (2), but the specific composition is preferably determined based on the following procedures (i) to (vi).

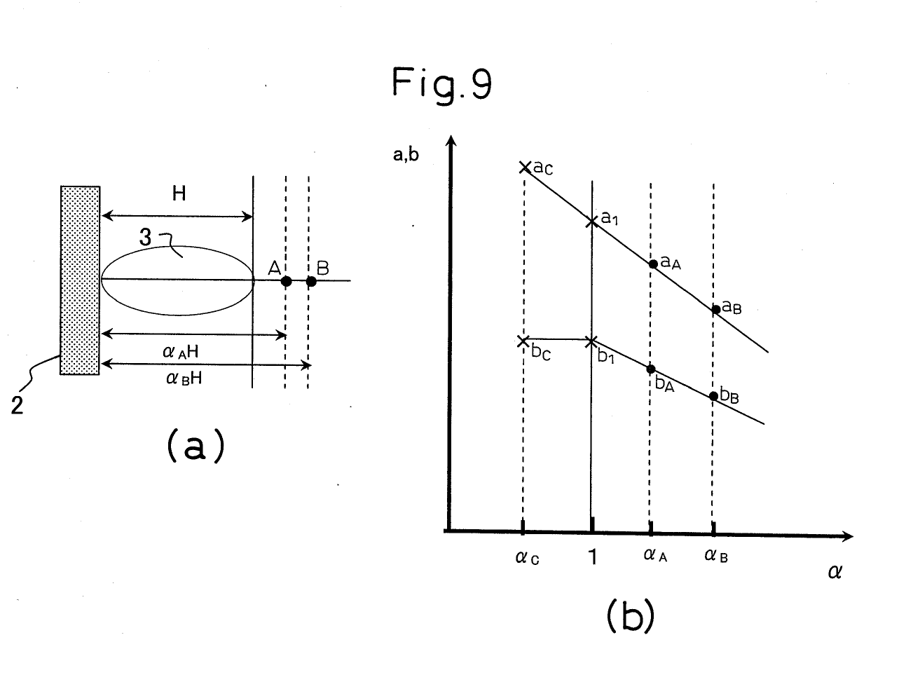

This will be explained based on FIG. 9. FIG. 9(a) shows the position of the substrate with respect to a plume of a height H, while FIG. 9(b) shows the setting technique.

(i) flexibly applying said formula (3) to select at least two substrate position coefficients α_{A} and α_{B} in a range of 1<α≦1.5 (see FIGS. 9(a) and (b)),

(ii) holding the substrate vertical to a center axis of the plume at two positions (see FIG. 9(a)) A (L_{A}=α_{A}H) and B (L_{B}=α_{B}H) on the center axis of the plume and firing a pulse laser at an oxide-based target of composition ratios 2RE/Ba=a and 3Ba/2Cu=b to form a film, wherein

(ii-1) making the film composition ratios 2RE/Ba and 3Ba/2Cu at the position A respectively a_{A} and b_{A} and

(ii-2) making the film composition ratios 2RE/Ba and 3Ba/2Cu at the position B respectively a_{B} and b_{B} (see FIG. 9(b)),

(iii) setting a film composition ratio coefficient f(α), wherein

(iii-1) determining a film composition ratio coefficient fₐ(α) based on the two points of (α_{A}, a_{A}) and (α_{B}, a_{B}) and

(iii-2) determining a film composition ratio coefficient f_{b}(α) based on the two points of (α_{A}, b_{A}) and (α_{B}, b_{B}),

(iv) entering α=α_{c}(<1) into fₐ(α) to calculate an estimated film composition ratio fₐ(α_{c})=a_{c} when forming a film by holding the substrate vertical to the center axis at the position of the substrate position coefficient α_{c} and entering α=1 into f_{b}(α) to calculate an estimated film composition ratio f_{b}(1)=b₁ when forming a film by holding the substrate vertical to the center axis at the tip of the plume (see FIG. 9(b)), wherein making this b₁ the estimated film composition ratio b_{c} at the position of the substrate position coefficient α_{c},

(v) comparing the calculated value a_{c} and the following formula (4) and comparing the calculated value b_{c} (=b₁) and the following formula (5), wherein

(v-1) if 1.0≦a_{c}≦1.2 and 0.8≦b_{c}(=b₁)<1.0, determining the composition ratios a (=2RE/Ba) and b (=3Ba/2Cu) as the composition ratios of the oxide-based target and

(v-2) if a_{c}<1.0 or 1.2<a_{c} and/or b_{c} (=b₁)<0.8 or 1.0≦b_{c} (=b₁), using the following procedure (vi) to determine the composition ratios a (=2RE/Ba) and b (=3Ba/2Cu) of the oxide-based target, and

(vi) calculating a_{c}−(1.0+1.2)/2=Δa and/or b_{c} (=b₁)−(0.8+1.0)/2=Δb and determining the composition ratios a (=2RE/Ba) and b (=3Ba/2Cu) of the oxide-based target as (a−Δa) and (b−Δb).

Note that, in the above procedure (iii), the film composition ratio coefficient f(α) was determined based on the two factors of the substrate position coefficient and film composition ratio, but it is also possible to select three or more substrate position coefficients and determine the coefficient by the least square method.

### (5) Energy of Pulse Laser

By specifically determining the composition of RE, Ba, and Cu forming the RE-Ba—Cu oxide-based target based on the above procedure, it is possible to form a RE123-based oxide superconducting film with almost no a-axis oriented crystal grains and having a uniform and dense c-axis oriented crystal structure having a 1 μm or more film thickness with a good reproducibility of film properties.

In the conventional PLD method holding the substrate outside the plume as well, attempts have been made to increase the film forming speed by changing the laser energy, but it is not possible to inhibit the growth of a-axis crystal grains or the nonsuperconducting phase degrading the critical current characteristic. The reproducibility of the film properties is also not that good.

In the final analysis, using the conventional PLD method to form a superconducting film having a 1 μm or more film thickness and having a critical current characteristic superior for practical use has never been reported up to now.

With the conventional PLD method of holding the substrate outside the plume, to suppress the growth of a-axis crystal grains, the energy density of the pulse laser fired on to the target is usually 1.5 to 2.0 J/cm², but in the film formation by the present invention, as shown in FIG. 2, usually the plume formed at the surface of the target is crushed in shape and spreads over the substrate surface. The film formation proceeds in this state, so it is possible to form a RE123-based oxide superconducting film superior in critical current characteristic by an energy density of 2.0 J/cm² or more.

Here, Table 3 shows the current density characteristic and X-ray diffraction intensity ratio of a-axis crystal grains of Gd123-based oxide films formed using a Gd_{0.9}Ba₂Cu_{3.3} oxide-based target containing a material supplying a nonsuperconducting phase (BaZrO₃ or ZrO₂) in 5 mol %, α=0.6 or 0.7, and a pulse laser energy density: 2.0 J/cm² and 3.5 J/cm² (samples b to e).

TABLE 3

| | | | | X-ray diffraction |
|---|---|---|---|---|
| | | Energy | | intensity ratio of |
| | Target | density of | Ic (3T) | a-axis crystal |
| Sample | material | pulse laser | (B//c) | grains |
| b | Gd_{0.9}Ba₂CU_{3.3}Oy | 3.5J/cm² | 110A | 7% |
| | + 5mol% BaZrO₃ | | | |
| c | Gd_{0.9}Ba₂Cu_{3.3}Oy | 3.5J/cm² | 80A | 17% |
| | + 5mol% ZrO₂ | | | |
| d | Gdo.9Ba2CU3.30y | 2.0J/cm² | 72A | 3% |
| | + 5mol% BaZrO₃ | | | |
| e | Gd0.9Ba2Cu3.30y | 2.0J/cm² | 30A | 3% |
| | + 5mol% ZrO₂ | | | |

From Table 3, it will be understood that a Gd123-based oxide superconducting film having a superior critical current characteristic is obtained, but if forming a film by an energy density of the pulse laser of 3.5 J/cm², a Gd123-based oxide superconducting film having a superior current characteristic which could not be realized in the past can be obtained.

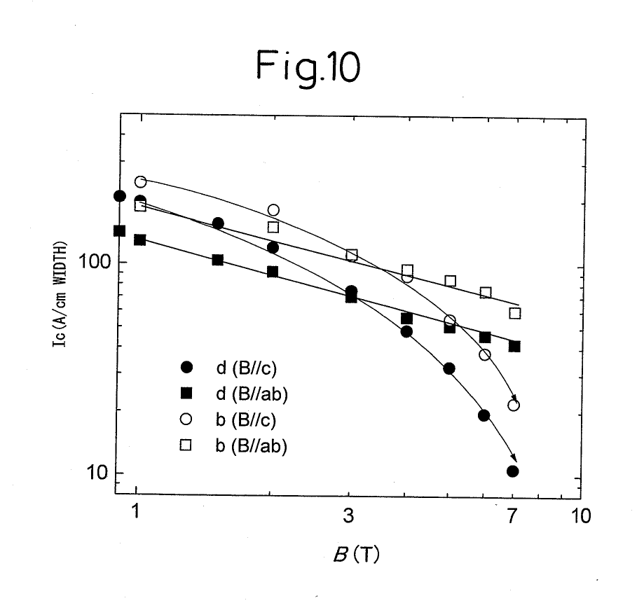

FIG. 10 shows the relationship between the magnetic field and the critical current Ic (A/cm width) of a Gd123-based oxide film formed using a Gd_{0.9}Ba₂Cu_{3.3} oxide-based target containing a 5 mol % of a nonsuperconducting phase material BaZrO₃ (sample b: film formed by pulse laser energy density 3.5 J/cm², sample d: film formed by pulse laser energy density: 2.0 J/cm²).

In the drawing, B//c shows the case of application of a magnetic field parallel to the c-axis of the crystals (vertical to film surface), while B//ab shows the case of application of a magnetic field parallel to the a·b planes of the crystal (parallel to film surface).

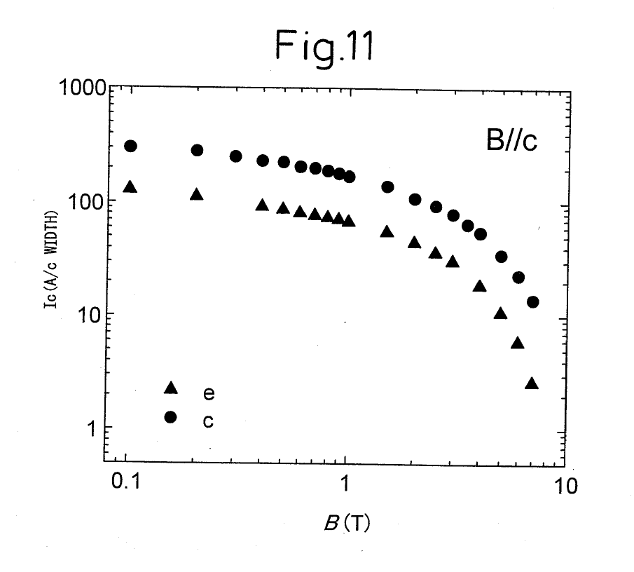

Further, FIG. 11 shows the relationship between the magnetic field and the critical current Ic (A/cm width) of a Gd123-based oxide film formed using a Gd_{0.9}Ba₂Cu_{3.3} oxide-based target containing 5 mol % of a nonsuperconducting phase material ZrO₂ (sample c: film formed by pulse laser energy density 3.5 J/cm², sample e: film formed by pulse laser energy density: 2.0 J/cm²).

From FIG. 10 and FIG. 11 as well, it is learned that the critical current characteristic of the Gd123-based oxide superconducting film formed by an energy density of the pulse laser of 3.5 J/cm² is superior to the critical current characteristic of the Gd123-based oxide superconducting film formed by an energy density of the pulse laser of 2 J/cm².

In the conventional PLD method holding the substrate outside of the plume, the energy density of the pulse laser, as explained above, is 2.0 J/cm² as a limit, but in the film formation of the present invention, it is possible to easily form a RE123-based oxide superconducting film superior in critical current characteristic at a 2.0 J/cm² or more energy density.

However, if the energy density of the pulse laser exceeds 5.0 J/cm², coarse CuO easily forms and uniform and dense RE123-based oxide superconducting film becomes difficult to obtain. For this reason, the energy density of the pulse laser is preferably 5.0 J/cm² or less.

### (6) Film Forming Speed

The film is formed in the present invention, as shown in FIG. 2, in the state with the plume crushed in shape and spreads to the substrate surface.

Inside the plume, plasma particles formed by ionization of the elements of the seed material of the target and the atmospheric gas are sprayed, while outside the plume, the plasma particles are believed to be sprayed while clustered (neutralized). That is, between the inside and outside of the plume, the physiochemical properties of the film forming atmosphere formed near the substrate surface differ. This difference is believed to have a large effect on the film forming speed and the reproducibility of the film properties.

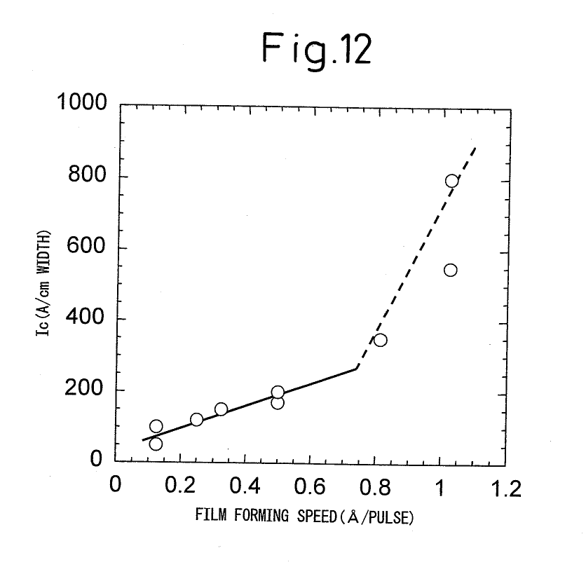

FIG. 12 shows the relationship between the film forming speed (Å/pulse) and critical current Ic (A/cm width).

In the drawing, the linear relationship where the film forming speed is 0.7 Å/pulse or less (in the drawing, the solid line) relates to the Gd123-based oxide film formed while holding the substrate outside the plume. The linear relationship where the film forming speed is 0.7 Å/pulse or more (in the drawing, broken line) relates to the Gd123-based oxide film formed while holding the substrate in the plume.

From FIG. 12, it is understood that when forming a film while holding the substrate in a plume, it is possible to easily form a Gd123-based oxide superconducting film by an extremely fast film forming speed with a critical current Ic (A/cm width) of over 300 A/cm width.

For this reason, when forming a film while holding the substrate in a plume, it is preferable to form the film by a 0.8 Å/pulse or more film forming speed.

The film forming speed (Å/pulse) may be suitably set in the range enabling maintenance of reproducibility of the film properties.

### (7) Film Thickness, Critical Current, and Volume Rate of C-Axis Oriented Crystal

As explained above, in the past, formation of a superconducting film having a 1 μm or more film thickness and having a high critical current characteristic sufficient for practical use has not yet been reported, but in the present invention, by more specifically determining the composition of the RE, Ba, and Cu forming the RE-Ba—Cu oxide-based target, it is possible to form a RE123-based oxide superconducting film with almost no a-axis oriented crystals present and having a uniform and dense c-axis oriented crystal structure having a 1 μm or more film thickness.

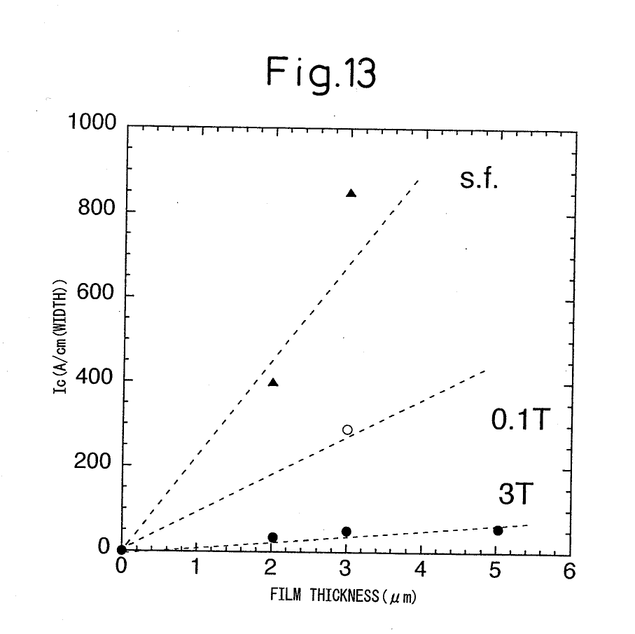

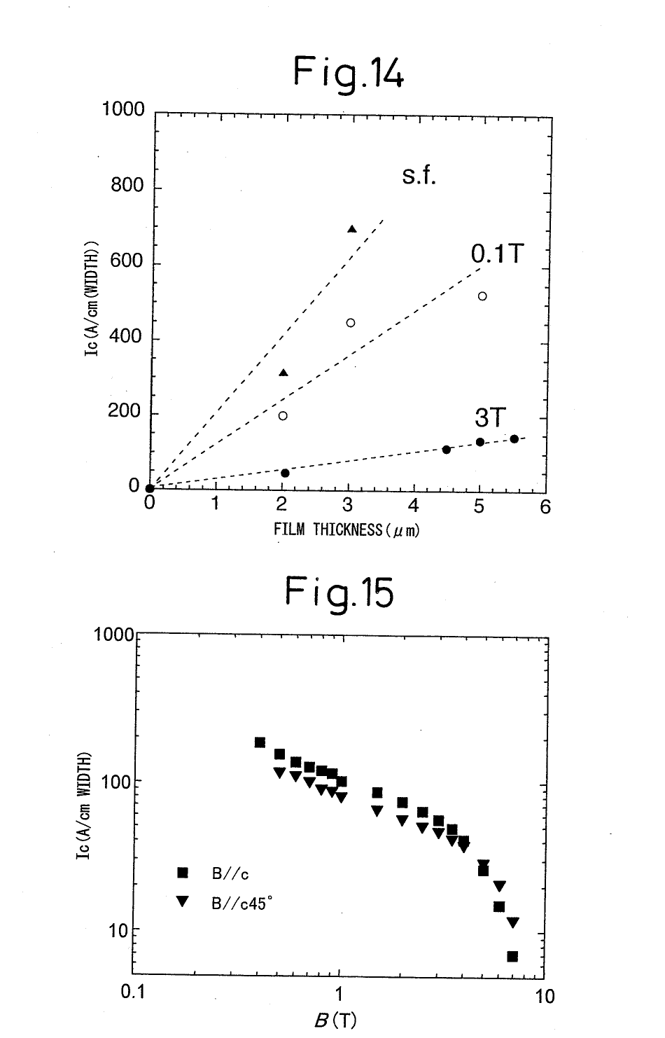

The inventors confirms this by measuring the relationship between the film thickness and critical current characteristic. Part of the results are shown in FIG. 13 and FIG. 14. FIG. 13 shows the relationship between the film thickness and critical current characteristic of a superconducting film formed using a Gd_{0.9}Ba₂Cu_{3.3} oxide-based target, while FIG. 14 shows the relationship between the film thickness and critical current characteristic of a superconducting film formed using a target comprised of Gd_{0.9}Ba₂Cu_{3.3} oxide in which 5 mol % of BaZrO₃ is dispersed.

As shown in FIG. 13 and FIG. 14, if using the present invention target and forming a film while holding the substrate in a plume, it is possible to easily obtain a Gd123-based oxide superconducting film having a film thickness of 3.0 μm and having a critical current in its own magnetic field of over 700 A/cm width (in the drawing, see s.f.)

As shown in FIG. 13, with a film thickness of 3.0 μm, the critical current in a 3 T external magnetic field (B//c) is “40 A/cm width”. The inventors confirmed that the RE123-based oxide superconducting film of the present invention has a “40 A/cm width or more” critical current in a 3 T magnetic field. This “3 T-40 A/cm width or more” is a value which cannot be achieved by the conventional PLD method holding the substrate outside the plume.

As shown in FIG. 14, when the film structure has 5 mol % of BaZrO₃ diffused in it, the critical current characteristic (Ic(A)) in the magnetic field tends to fall somewhat, but the critical current (Ic(A)) in an external magnetic field is conversely improved to 100 A/cm width. Further, the inventors confirmed that a RE123-based oxide superconducting film containing a nonsuperconducting substance in the film structure in 7 mol % or less has a 60 A/cm width or more critical current characteristic without regard as to the direction of application of the magnetic field a 3 T magnetic field.

Note that, the critical current characteristic of the RE123-based superconducting film in a magnetic field will be explained in detail in the section on EXAMPLES.

As explained above, the RE123-based oxide superconducting film of the present invention is provided reliably with a practical level of critical current characteristic with a film thickness of 1 μm or more.

The quality of the critical current characteristic depends on the quality of the film structure, so providing the RE123-based oxide superconducting film with a film thickness of 1.0 μm or more and a practical level of critical current characteristic can be said to mean that even if the film structure has a-axis oriented crystal grains degrading the critical current characteristic, they are very small in amount and that a uniform and dense c-axis oriented crystal structure is formed over the entire film thickness direction.

According to Table 3, even with a Gd123-based oxide film (sample c) with an X-ray diffraction intensity ratio of a-axis crystal grains of 17%, a practical level of a critical current characteristic of 80 A can be obtained, so the film structure of the RE123-based oxide superconducting film is preferably one where the c-axis oriented crystals are present over the entire film thickness direction in a volume ratio of 80% or more.

### (8) Material of Substrate

The substrate used in the present invention need only be one enabling formation of a RE123-based oxide superconducting film and is not limited to one of a specific grade, but if assuming use of the RE123-based superconductor as a wire material, a drawable metal substrate, in particular a long metal substrate, is preferable. Specifically, for example, Hastelloy laminated with MgO, Gd₂Zr₂O₇, CeO₂, LaMnO₃, or another oxide is preferable.

The fact that if holding a substrate in the plume, it is possible to form a film by a faster film forming speed than the past can be said to mean that a film can be formed by a faster film forming speed than the past even for a substrate running through the plume at the required speed. Therefore, the present invention can also be applied to a long metal substrate moving at a required speed.

That is, the present invention enables the formation of a RE123-based oxide superconducting film provided with a practical level of critical current characteristic by a required speed on a long metal substrate running through a plume with good reproducibility of the film properties.

### Examples

Next, examples of the present invention will be explained, but the conditions of the examples are just a single illustration of the conditions employed for confirming the workability and effects of the present invention. The present invention is not limited to this illustration. The present invention can employ various conditions so long as not departing from the gist of the present invention and achieving the object of the present invention.

### Example 1

Using a Gd_{0.9}Ba₂Cu_{3.3} oxide-based target (2Gd/Ba=0.90, 3Ba/2Cu=0.91), a substrate comprised of Hastelloy covered by Gd₂Zr₂O₇ and, furthermore, covered over that by CeO₂ (ΔΦ=4.8°) was held in the plume (height 6 to 8 cm). The substrate was formed with a Gd123-based oxide superconducting film under a substrate temperature: 820 to 840° C., oxygen partial pressure in the atmosphere: 350 to 380 mmTorr, and the conditions shown in Table 3.

The thickness and structure (X-ray diffraction intensity ratio f a-axis crystal grains) of the grown Gd123-based oxide superconducting film are shown together in Table 4.

As shown in Table 4, the Gd123-based oxide superconducting films of samples a to e all had thicknesses of 3 μm or more. Their structures had a ratio of c-axis oriented crystals of 80% or more compared with the X-ray diffraction intensity ratio of a-axis crystal grains.

TABLE 4

| | | | | | | X-ray |
|---|---|---|---|---|---|---|
| | | Base | | | | diffraction |
| | Added non- | material | Pulse laser | Film | | intensity |
| | superconducting | position | energy | forming | Film | ratio of a- |
| | material in | coefficient | density | speed | thickness | axis crystal |
| Sample | target | (α) | (J/cm²) | (Å/pulse) | (μm) | grains |
| a | None | 0.7 | 3.5 | 1 | ≧3 | 3% |
| b | BaZrO₃, 5 mol % | 0.7 | 3.5 | 1 | ≧3 | 7% |
| c | ZrO₂, 5 mol % | 0.7 | 3.5 | 1 | ≧3 | 17% |
| d | BaZrO₃, 5 mol % | 0.6 | 2.0 | 1 | ≧3 | 3% |
| e | ZrO₂, 5 mol % | 0.6 | 2.0 | 1 | ≧3 | 3% |

### Example 2

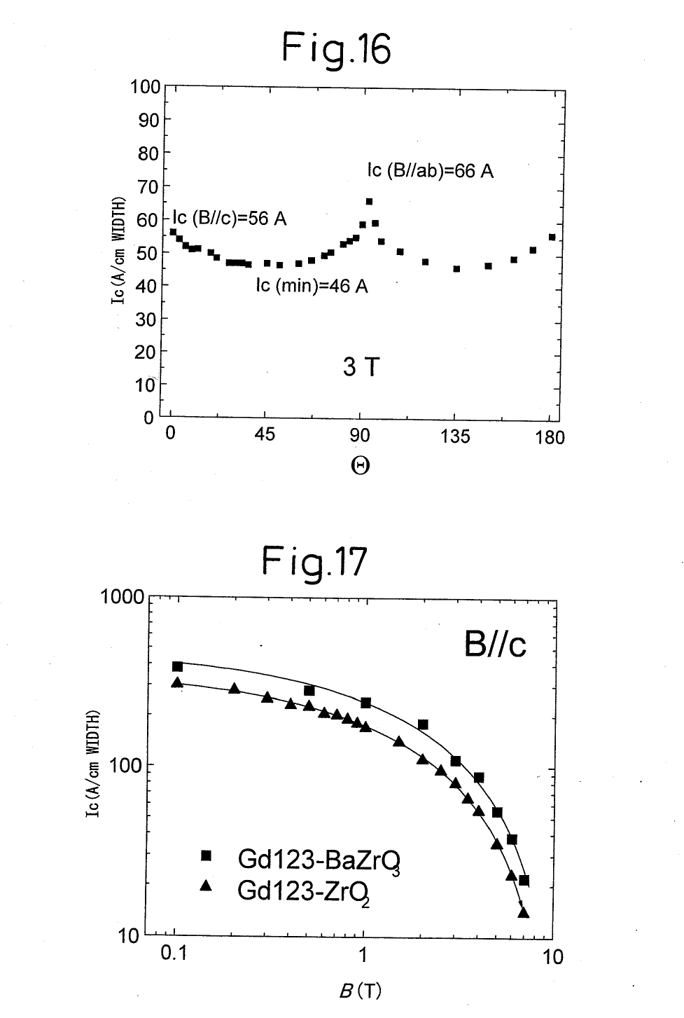

The Gd123-based oxide superconducting film of the sample a was measured for the critical current characteristic in a magnetic field. The results are shown in Table 5 and FIG. 15 and FIG. 16. Table 5 also describes the X-ray diffraction intensity ratio of a-axis crystal grains.

FIG. 15 shows the magnetic field strength dependency of the critical current characteristic in the case of applying a magnetic field B from 0.3 T to 7 T, while FIG. 16 shows the dependency of the critical current characteristic on the direction of application of the magnetic field.

TABLE 5

| | | Ic (3T) | X-ray diffraction |
|---|---|---|---|
| Target | Ic (3T) | (minimum | intensity ratio of a-axis |
| material | (B//c) | value) | crystal grains |
| Gd_{0.9}Ba₂Cu_{3.3}Oy | 56A | 46A | 3% |

In FIG. 15, the black squares (B//c) show the case of applying a magnetic field B in parallel to the c-axis of the crystals, while the black upside down triangles) (B//c45°) show the case of applying a magnetic field B from a direction 45° from the c-axis of the crystals.

Even if applying a magnetic field up to 7 T, it is learned that a current of 10 A/cm width or more runs through a Gd123-based oxide superconducting film. Such a high value is a value which cannot be obtained by the conventional PLD method.

In FIG. 16, the case when applying a magnetic field B(3 T) vertically to the surface of the Gd123-based oxide superconducting film is defined as 0°. The critical current is even at the least a 46 A/cm width.

This shows that in the structure of a Gd123-based oxide superconducting film, there is no cleavage of the current path due to the existence of a coarse nonsuperconducting phase and no deterioration of grain boundary bonds due to large slant angle grain boundaries, Ba compounds, etc. Note that such a high value is a value which cannot be obtained by the conventional PLD method.

### Example 3

The Gd123-based oxide superconducting films (containing nonsuperconducting substances) of the samples b to e shown in Table 4 were measured for the critical current characteristic in the magnetic field. The results are shown in FIGS. 17 to 19. Further, the result is as shown in the above-mentioned Table 3.

From FIG. 17, it is learned that even if applying a magnetic field up to 7 T, a 10 A/cm width or more current will run through the Gd123-based oxide superconducting film. Such a high value is a value which cannot be obtained by the conventional PLD method.

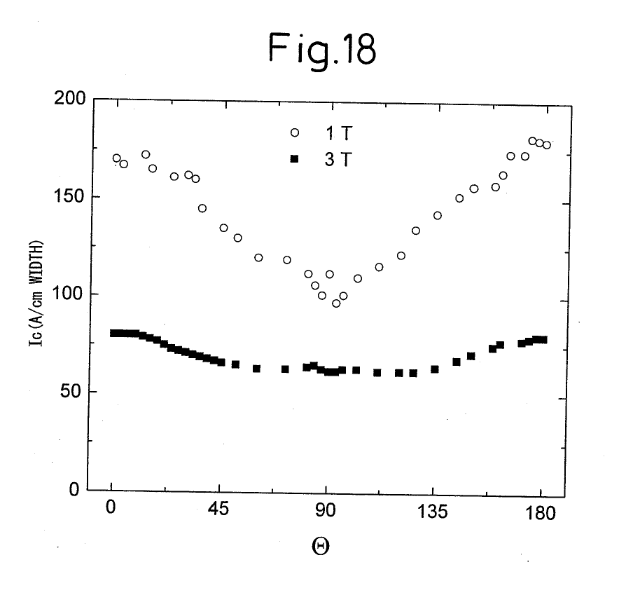

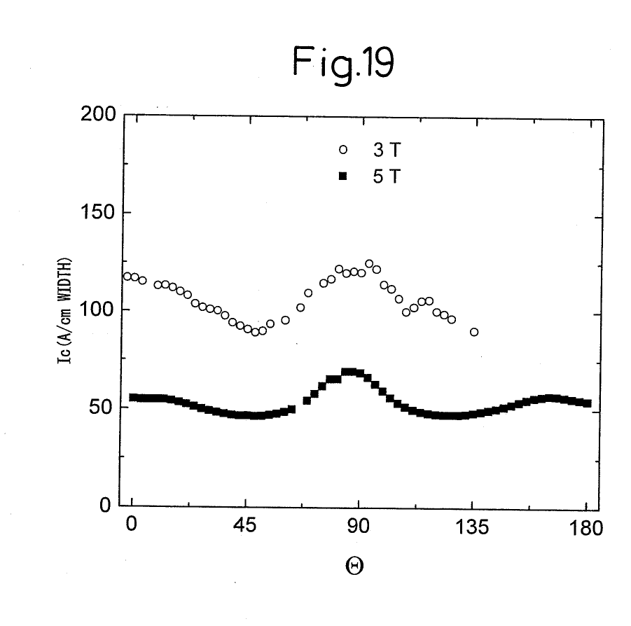

From FIG. 18 and FIG. 19, it is learned that when applying a magnetic field B(3 T) vertically to the surface of the Gd123-based oxide superconducting film, at the very least a 72 A/cm width critical current is obtained.

This shows that in the superconducting phase of the RE123-based oxide superconducting film, there is cleavage of the current path due to the existence of a nonsuperconducting phase coarsened in the a-axis or b-axis direction of the crystals and no deterioration of grain boundary bonds due to large slant angle grain boundaries, Ba compounds, etc. and, in addition, the nonsuperconducting phase dispersed in the superconducting phase effectively functions as a pinning center for pinning the magnetic flux. Such a high value is also a value which cannot be obtained by the conventional PLD method.

### INDUSTRIAL APPLICABILITY

As explained above, according to the present invention, it is possible to provide a RE123-based superconductor obtained by forming a RE123-based superconducting film with Ba smaller than the stoichiometric composition on a substrate by a faster film forming speed than the past and having a superior critical current characteristic sufficient for practical use in its own magnetic field and in an external magnetic field. Further, if using a metal substrate able to be drawn as the substrate, the RE123-based superconductor of the present invention can be used as the material for a wire.

Accordingly, the present invention has a high applicability in technical fields using superconductivity.

1. A method of production of a RE123-based oxide superconductor, said method of production of a RE123-based oxide superconductor characterized by comprising
(i) firing a pulse laser at an oxide-based target including RE, Ba, and Cu satisfying the following formulas (1) and (2) to form a plume and
(ii) holding a substrate in that plume to form an RE123-based oxide superconducting film:
0.8≦2RE/Ba<1.0 (1)
0.8.≦3Ba/2Cu<1.0 (2)
where, RE is one or more of Y, La, Nd, Sm, Eu, Gd, Dy, Ho, and Er.

2. A method of production of a RE123-based oxide superconductor as set forth in claim 1 characterized by adding to said oxide-based target, as a material of a nonsuperconducting substance to be introduced dispersed into the RE123-based oxide superconducting film, one or more of ZrO₂, BaZrO₃, BaSnO₃, BaCeO₃, BaHfO₃, and BaRuO₃ in a total of 7 mol % or less.

3. A method of production of a RE123-based oxide superconductor as set forth in claim 1 characterized by holding said substrate at a position satisfying the following formulas (3):
L=α·H (3)
where,
L: length between target and substrate (cm)
H: height of plume without substrate (cm)
α: substrate position coefficient, 0.6≦α≦0.9.

4. A method of production of a RE123-based oxide superconductor as set forth in claim 1 characterized in that said RE123-based oxide superconducting film has a composition satisfying the following formulas (4) and (5):
1.0≦2RE/Ba≦1.2 (4)
0.8≦3Ba/2Cu<1.0 (5).

5. A method of production of a RE123-based oxide superconductor as set forth in claim 2 characterized in that said RE123-based oxide superconducting film has a superconducting phase of a composition satisfying the following formulas (4) and (5):
1.0≦2RE/Ba≦1.2 (4)
0.8≦3Ba/2Cu<1.0 (5).

6. A method of production of a RE123-based oxide superconductor as set forth in claim 1 characterized by determining a composition of an oxide-based target satisfying said formulas (1) and (2) in accordance with the following procedures (i) to (vi):
(i) flexibly applying said formula (3) to select at least two substrate position coefficients α_{A} and α_{B} in a range of 1<α≦1.5;
(ii) holding the substrate vertical to a center axis of the plume at two positions A (L_{A}=α_{A}H) and B (L_{B}=α_{B}H) on the center axis of the plume and firing a pulse laser at an oxide-based target of composition ratios 2RE/Ba=a and 3Ba/2Cu=b to form a film, wherein
(ii-1) making the film composition ratios 2RE/Ba and 3Ba/2Cu at the position A respectively a_{A} and b_{A} and
(ii-2) making the film composition ratios 2RE/Ba and 3Ba/2Cu at the position B respectively a_{B} and b_{B},
(iii) setting a film composition ratio coefficient f(α), wherein
(iii-1) determining a film composition ratio coefficient fₐ(α) based on the two points of (α_{A}, a_{A}) and (α_{B}, a_{B}) and
(iii-2) determining a film composition ratio coefficient f_{b}(a) based on the two points of (α_{A}, b_{A}) and (α_{B}, b_{B}),
(iv) entering α=α_{C}(<1) into fₐ(α) to calculate an estimated film composition ratio fₐ(α_{C})=a_{C} when forming a film by holding the substrate vertical to the center axis at the position of the substrate position coefficient α_{C} and entering α=1 into f_{b}(α) to calculate an estimated film composition ratio f_{b}(1)=b₁ when forming a film by holding the substrate vertical to the center axis at the tip of the plume, wherein making this b₁ the estimated film composition ratio b_{C} at the position of the substrate position coefficient α_{C},
(v) comparing the calculated value a_{C} and the following formula (4) and comparing the calculated value b_{C} (b₁) and the following formula (5), wherein
(v-1) if 1.0≦a_{C}≦1.2 and 0.8≦b_{C}(=b₁)<1.0, determining the composition ratios a (=2RE/Ba) and b (=3Ba/2Cu) as the composition ratios of the oxide-based target and
(v-2) if a_{C}<1.0 or 1.2<a_{C} and/or b_{C} (=b₁)<0.8 or 1.0b_{C} (=b₁), using the following procedure (vi) to determine the composition ratios a (=2RE/Ba) and b (=3Ba/2Cu) of the oxide-based target, and
(vi) calculating a_{C}−(1.0+1.2)/2=Δa and/or b_{C} (=b₁)−(0.8+1.0)/2=Δb and determining the composition ratios a (=2RE/Ba) and b (=3Ba/2Cu) of the oxide-based target as (a−Δa) and (b−Δb):
1.0≦2RE/Ba≦1.2 (4)
0.8≦3Ba/2Cu<1.0 (5).

7. A method of production of a RE123-based oxide superconductor as set forth in claim 1 characterized in that the pulse laser fired at said oxide-based target has an energy density of 2 to 5 J/cm².

8. A method of production of a RE123-based oxide superconductor as set forth in claim 1 characterized by forming said RE123-based oxide superconducting film at a 0.8 A/pulse or more of film forming speed.

9. A method of production of a RE123-based oxide superconductor as set forth in claim 1 characterized in that in said RE123-based oxide superconducting film, (i) a film thickness is 1.0 μm or more and (ii) c-axis oriented crystals are present over the entire thickness direction in a volume rate of 80% or more.

10. A method of production of a RE123-based oxide superconductor as set forth in claim 1 characterized in that said RE is Gd.

11. A method of production of a RE123-based oxide superconductor as set forth in claim 1 characterized in that said substrate is a metal substrate.

12. An RE123-based oxide superconductor characterized by being produced by a method of production of a RE123-based oxide superconductor as set forth in claim 1.

13. An RE123-based oxide superconductor produced by a method of production of a RE123-based oxide superconductor as set forth in claim 1, said RE123-based oxide superconductor characterized in that the RE123-based oxide superconducting film has a 40 A/cm width or more critical current characteristic in a 3 T magnetic field.

14. An RE123-based oxide superconductor as set forth in claim 13 characterized in that said RE123-based oxide superconducting film has a composition satisfying the following formulas (4) and (5):
1.0≦2RE/Ba≦1.2 (4)
0.8≦3Ba/2Cu<1.0 (5).

15. An RE123-based oxide superconductor produced by a method of production of a RE123-based oxide superconductor as set forth in claim 2, said RE123-based oxide superconductor characterized in that the RE123-based oxide superconducting film has a 60 A/cm width or more critical current characteristic in a 3 T magnetic field.

16. An RE123-based oxide superconductor as set forth in claim 15 characterized in that said RE123-based oxide superconducting film has a superconducting phase of a composition satisfying the following formulas (4) and (5):
1.0≦2RE/Ba≦1.2 (4)
0.8≦3Ba/2Cu<1.0 (5).

17. An RE123-based oxide superconductor as set forth in claim 12 characterized in that in said RE123-based oxide superconducting film, (i) a film thickness is 1.0 μm or more and (ii) c-axis oriented crystals are present over the entire thickness direction in a volume rate of 80% or more.
